(19) United States
(12) Patent Application Publication
(10) Pub. No.: US 2005/0223988 A1
(43) Pub. Date: Oct. 13, 2005

(54) Coating device comprising a conveying device

(76) Inventors: Stephen Behle, Hahnheim (DE); Andreas Luttringhaus-Henkel, Darmstadt (DE); Harmut Bauch, Weilrod (DE)

Correspondence Address: Charles N J Ruggiero;Ohlandt Greeley Ruggiero & Perle, 10th Floor, One Landmark Square, Stamford, CT, 06901-2682, US

(21) Appl. No.: 10/515,038

(22) PCT Filed: May 26, 2003
(86) PCT No.: PCT/EP03/05498

§ 371 Date: May 6, 2005

(30) Foreign Application Priority Data
May 24, 2002 (DE) 102 23 288.1
Jun. 1, 2002 (DE) 102 24 395.6
Jun. 20, 2002 (DE) 102 27 637.4
Mar. 28, 2003 (DE) 13 14 067.0

(51) Int. Cl. C23C 16/00

(52) U.S. Cl. 118/719

(57) ABSTRACT

An apparatus and method for a vacuum coating of substrates is provided. The apparatus for vacuum coating of substrates includes a conveyor device, at least one coating station having a plurality of coating places, which is conveyed on the conveyor device, an evacuation device, as well as a device for rotating the coating places on the conveyor device.

The invention deals in general terms with the coating of substrates, and relates in particular to an apparatus and a process for the deposition of functional layers by means of an apparatus having a conveyor device for the substrates that are to be coated.

To improve the barrier actions in particular of plastic containers, such as for example plastic bottles, these containers can be provided with barrier layers. Plastic containers, such as for example plastic bottles often have a barrier action to gases which is insufficient for the intended use. By way of example, it is possible for gases, such as carbon dioxide, to diffuse out of plastic bottles or into them. This effect is generally undesirable in particular when storing foodstuffs, since this effect can shorten the shelf life of foodstuffs stored in these containers. Barrier coatings can reduce the diffusion through the container walls by orders of magnitude.

Various vapor deposition techniques, such as physical or chemical vapor deposition, have proven particularly suitable for the application of barrier coatings and other functional layers. With these techniques, it is possible, inter alia, to produce very dense inorganic layers which are securely bonded to the surface of the work piece and have a good barrier action.

However, these processes are relatively complex, since the substrates that are to be coated for this purpose have to be placed under a vacuum and then discharged again after coating has been completed. In particular for coatings on an industrial scale, this requires a machine with a correspondingly high power. By way of example, rotary or linear apparatuses, in which substrates are supplied, coated and removed again continuously, are suitable for this purpose. Problems arise in this respect inter alia if the layers to be deposited require long coating times. By way of example, certain coatings may require coating times alone of longer than 20 seconds. In such cases, a continuously running rotary apparatus can no longer be operated economically, since it either has to move at a correspondingly slow speed or its size has to be matched to the process times, which requires very large and correspondingly expensive machines.

Therefore, the invention is based on the object of making the vacuum coating of substrates or work pieces more economical.

This object is achieved, in a surprisingly simple way, by an apparatus for the coating of substrates as claimed in claim 1 and a process for the coating of substrates as claimed in claim 23. Advantageous refinements form the subject matter of the corresponding subclaims.

Accordingly, the invention provides an apparatus for the vacuum coating of substrates, which comprises
a conveyor device,
at least one coating station or plasma station having a plurality of coating places, which is conveyed on the conveyor device, and
an evacuation device. Moreover, the apparatus has a device for rotating the coating places of the coating station on the conveyor device.

The process according to the invention, for the vacuum coating of substrates, which can be carried out in particular by means of an apparatus according to the invention, comprises the steps of
loading a coating station with a plurality of substrates that are to be coated,
evacuating the coating or plasma station,
conveying the coating station on a conveyor device,
vacuum coating the substrates,
venting the coating station, and
removing the coated substrates, in which process the coating places of the coating station are rotated on the conveyor device.

For the apparatus according to the invention and the process for vacuum coating, a suitable conveyor device is, for example, a conveyor carousel or a linear conveyor device, or a rectilinear conveyor. In the embodiment of the invention with a conveyor carousel, the axis of rotation of the coating places is preferably parallel to the axis of rotation of the conveyor carousel or plasma wheel.

The coating operation is carried out for a plurality of substrates simultaneously by means of a coating station having a plurality of coating places. As a result, for a given process duration, the throughput can be increased by a factor corresponding to the number of coating places compared to an apparatus having individual coating places. However, this gives rise to the problem of accessibility to all the coating places. According to the invention, this problem is solved by the coating places being rotated, so that each coating place can be made accessible from one position.

In the process according to the invention, the coating places are not necessarily rotated throughout the entire process sequence. Rather, this rotation may preferably take place during a process step in which the coating places are to be made accessible. According to a preferred embodiment of the invention, a rotation is carried out in particular during the loading operation. According to a preferred embodiment of the invention, for this purpose the coating places are rotated, by means of a suitably designed device for rotation of the coating places, in order to be loaded with substrates, in such a way that the coating places are successively moved into a loading position. This can be carried out both for each coating place individually or for a combination of coating places in groups.

The removal of the coated substrates can be facilitated in the same way if the coating places are rotated during the removal operation. For this purpose, the coating station can be rotated by means of a suitably designed device for rotating the coating places in order for substrates to be removed from the coating places, so that the coating places are successively moved into a removal position.

It is not absolutely imperative that the entire coating station be rotated in order to rotate the coating places on the conveyor device. Rather, the coating station may advantageously also be equipped with a rotatable substrate carrier. For example, the coating station may be arranged in a fixed position on the conveyor device, with the substrate carrier then being rotated in order to rotate the coating places.

Moreover, according to a refinement of this embodiment, the substrate carrier has through-passages which connect a side of the carrier facing the coating places to an opposite side of the carrier. Moreover, the coating station may comprise a base plate with supply passages, which can be brought together with the substrate carrier in order to produce a connection to the evacuation device and/or to supply process gas. By way of example, the supply passages in the base plate can be connected to the through-passages in the substrate carrier. The supply passages in this case preferably serve to evacuate and supply process gas or as a cutout for a gas lance, for example, to be introduced into.

In an advantageous refinement of the apparatus according to the invention, the latter also comprises a suitable loading device and/or removal device for loading and removing the substrates. Both the loading of the coating station using the loading device and the removal using the removal device can be effected in a simple way by means of at least one allocation wheel.

According to a particularly preferred embodiment of the invention, the vacuum coating comprises plasma coating or plasma-enhanced chemical vapor deposition (PECVD) on the substrates. Accordingly, in this embodiment of the invention, the apparatus for the vacuum coating of substrates comprises a device for the plasma coating of the substrates. The plasma coating device may advantageously also comprise a device for introducing process gas.

The plasma coating of substrates is particularly suitable, by way of example, for also coating nonplanar or significantly convex surfaces of substrates without shadowing or incidence angle effects occurring. For plasma coating, a plasma is ignited in a gas which shrouds the surface to be coated. Then, a layer is deposited on the surface from the reaction products which form in the plasma. This process can be used to produce a very wide range of layer compositions by suitable selection of the composition of the process gas.

In this context, it is preferable for the plasma to be generated by the action of electromagnetic waves, in particular of microwaves on the process gas. For this purpose, the device for plasma coating comprises a device for generating electromagnetic waves, in particular for generating microwaves. These waves are fed to the coating places, where a plasma is formed as a result of interaction with process gas of a suitable density which is present.

Moreover, a preferred variant of this embodiment of the invention provides for the electromagnetic waves to be pulsed. This form of CVD coating is also known as plasma impulse chemical vapor deposition or PICVD. Coating by means of a pulsed plasma is advantageous, inter alia, because it reduces the thermal load on the substrates in accordance with the duty factor. Even very temperature-sensitive substrates, such as for example plastic bottles, can be plasma-coated in this way. A further advantage of this variant of the plasma coating is that successful exchange of the process gas is possible in the pulse spaces. This avoids an increase in the levels of undesired reaction products which form in the plasma.

To achieve a high throughput through the apparatus according to the invention and to maintain short process times in the apparatus, moreover, it is advantageous for the coating station to be evacuated as quickly as possible. For this purpose, it has proven advantageous for the evacuation to be carried out in a number of stages. Therefore, the evacuation device may advantageously comprise a plurality of pump stages.

Furthermore, it is advantageous if the evacuation device also comprises a device for sequentially connecting the coating station to a plurality of pump stages in order to achieve rapid evacuation. By way of example, the pump stages can each operate in a defined pressure range. In particular, it is in this way possible for a plurality of coating stations to be evacuated simultaneously, with each of these coating stations being connected to one pump stage. In particular, in this respect, the apparatus according to the invention may particularly advantageously have a vacuum system as described in the German application bearing application number 102 53 512.4, the content of disclosure of which in this respect is hereby incorporated in its entirety in the subject matter of the present invention.

Furthermore, it is possible to use pumps of the same type and for coating stations which follow one another in the direction of movement to be alternately connected to the respective pumps.

A preferred embodiment of the invention provides for the coating of substrates which are in the form of hollow bodies, such as for examples bottles, spherical caps or ampoules. For this purpose, the coating places may have suitable receptacles for such substrates in the form of hollow bodies. These receptacles may preferably also be designed in such a way as to seal off the interior of the substrates from the environment surrounding the substrates. It is then possible, for example, for the interior of the substrates in the form of hollow bodies to be evacuated separately using a suitable device. This is advantageous, inter alia, if only internal or external coating of the substrates is to be performed. If, for example, internal coating is performed, it is sufficient for the outer region to be evacuated only to a sufficient extent for the substrate to withstand the pressure difference between inner and outer regions.

For many applications, in particular internal coating of substrates in the form of hollow bodies is expedient. By way of example, for the barrier action it is considerably better if there is a barrier coating on the inner side of the substrates. To perform internal coating, a separate supply of process gas into the interior of the substrates by means of a suitable device is advantageous. This device may, for example, comprise a gas lance which is introduced into the interior, where it ensures good and rapid distribution of the process gas. When the interior has been filled with process gas, it is possible to ignite a plasma in the interior of the substrates by introducing electromagnetic waves into the coating station, resulting in internal coating of the substrates.

According to a further advantageous refinement of the apparatus according to the invention, the at least one coating station having a plurality of coating places has a reactor with a moveable sleeve part or a moveable chamber wall and a substrate carrier or chamber base, with at least one sealed coating chamber or plasma chamber being defined between sleeve part and substrate carrier in the position in which they butt against one another. The moveable configuration of the sleeve part means that the coating place is very accessible in the open position of the coating station, since the substrates do not have to be introduced into the sleeve part, but rather the latter is fitted over the substrates when the coating station is closed. A coating station designed in this way is also described in the German application bearing application number 102 53 512.2, the content of disclosure of which in this respect is also incorporated in its entirety in the subject matter of the present invention.

In an advantageous refinement of the invention, the opening and closing of the coating station can be effected by a suitable hydraulic, pneumatic or electrical device. Another simple option consists in the opening and closing being produced by the coating station being guided past at least one mechanical control cam.

In addition to the preferred option of plasma coating, it is also possible for other coating processes, such as for example PVD coating, to be implemented by means of a corresponding device in the apparatus according to the invention. PVD coating is advantageous, inter alia, if electrically conductive layers are to be deposited.

The invention is explained in more detail below on the basis of specific embodiments and with reference to the appended drawings, in which identical reference symbols denote identical or similar parts. In the drawings:

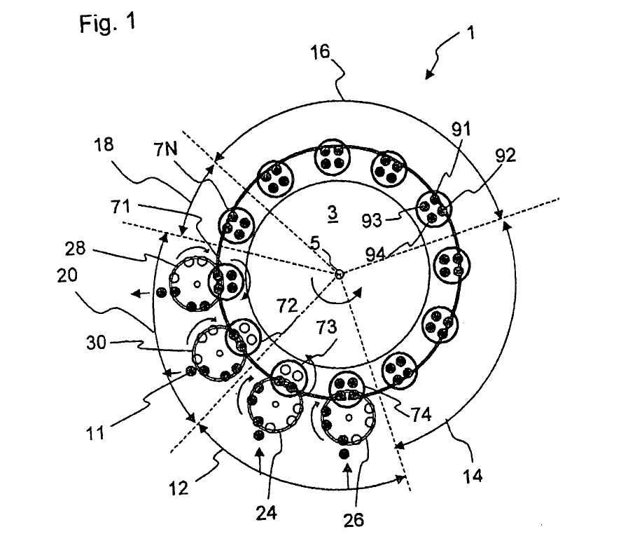

FIG. 1 shows a diagrammatic plan view of an embodiment of an apparatus according to the invention,

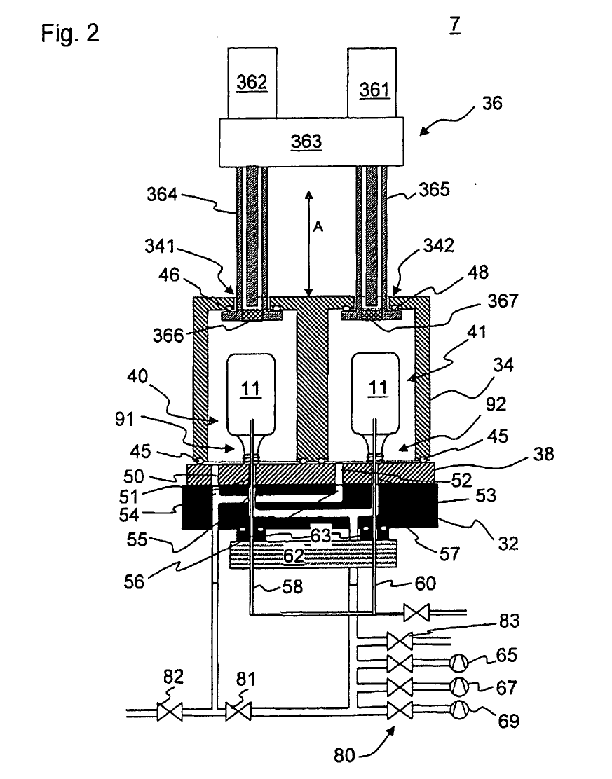

FIG. 2 shows a section through an embodiment of a coating station, and

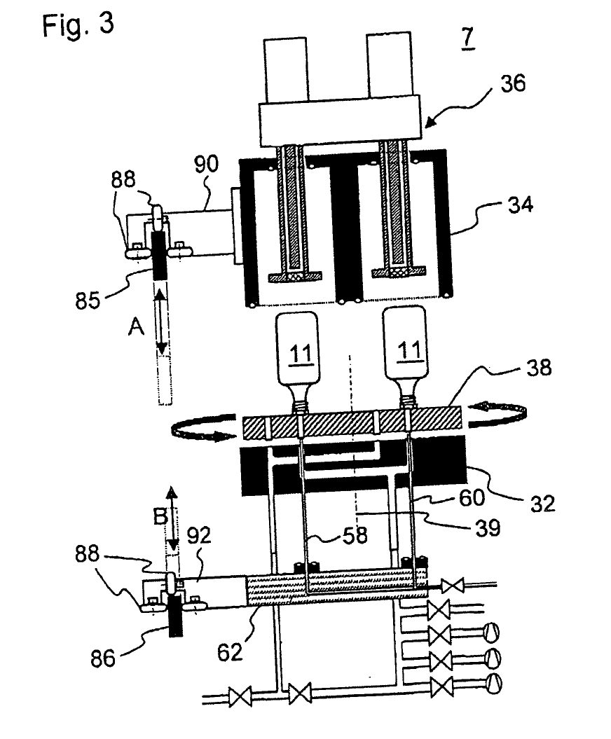

FIG. 3 shows a cross-sectional view through an embodiment of a coating station with control of the opening and closing operation by means of mechanical control cams.

FIG. 1 illustrates a first embodiment of an apparatus according to the invention for the vacuum coating of substrates, which is denoted overall by reference numeral 1.

The apparatus 1 comprises a conveyor device with a conveyor carousel 3 which rotates about an axis of rotation 5.

A multiplicity of coating stations 71, 72, 73, 74, . . . , 7N are arranged on the conveyor carousel 3 and are conveyed by means of the conveyor device.

Moreover, the coating stations, 71, 72, 73, 74, . . . , 7N each have a plurality of coating places; in the embodiment illustrated in FIG. 1, by way of example, each coating station has four coating places 91, 92, 93, 94. The coating places of a coating station can be rotated with respect to the conveyor device by means of a device for rotating the coating places, as indicated by the arrows in FIG. 1. In this embodiment of the invention, furthermore, the axis of rotation of the coating places of the coating stations is parallel to the axis of rotation 5 of the conveyor carousel.

The coating process is carried out while the conveyor carousel 3 is rotating. The various process steps can be assigned to specific circle sectors which the coating places 91, 92, 93, 94 of the coating stations 71, 72, . . . , 7N conveyed by the carousel 3 pass through as the carousel rotates. First of all, the coating places of the coating stations are loaded in a first circle sector 12. This is done by means of a loading device with two allocation wheels or loading wheels 24 and 26. To load the coating places 91-94, the latter are moved successively, by rotation on the conveyor device, into a loading position, in which the coating places to be loaded face outward. In this embodiment of the invention, in particular, the coating places are successively moved into a loading position in two groups of in each case two coating places and are then jointly loaded by an allocation wheel 24 or 26.

Then, once the loading of the coating places is complete, the coating stations are conveyed through an evacuation sector 14, where the coating stations are evacuated, preferably in a plurality of stages. For this purpose, a plurality of pumps stages which operate in different pressure ranges are successively connected to the coating stations 71, 72, 7N.

The coating stations then pass through a coating sector 16. The vacuum coating is carried out as they pass through this sector. In this context, it is preferable to carry out a plasma coating, with a process gas being supplied and electromagnetic waves being radiated into the regions which have been filled with the process gas, in order to generate a plasma. The coating is particularly preferably carried out using a pulsed plasma or pulsed electromagnetic waves, in order to reduce the thermal load on the substrates and to improve the exchange of process gas in the pulse spaces.

After coating has been completed, the coating stations are vented as they pass through a venting sector 18 and opened. Then, the coated substrates 11 are removed during passage through a removal sector 20, by means of a removal device with allocation wheels or removal wheels 28, 30. The removal of the substrates 11 from the coating places 91 to 94 is carried out in a similar way to the loading operation. In this case too, two groups of coating places are successively moved into a removal position facing outward on the conveyor carousel, and in each case two substrates from a group of two coating places are removed by an allocation wheel 28 or 30. The movement into the removal position is likewise effected through rotation of the coating places with respect to the conveyor device or the conveyor carousel 3.

In this embodiment of the invention, it is easy to realize a continuous circulation of the coating stations 71-7N on the conveyor device, since the loading and removal are in each case carried out by means of a plurality of allocation wheels past which the coating stations are guided. Of course, however, discontinuous operation is also possible, in which case circulation of the conveyor carousel 3 takes place in steps.

FIG. 2 shows a section through an embodiment of a coating station, which is denoted overall by 7. The coating station 7 comprises a reactor having a moveable sleeve part 34 and a base plate or carrier plate 32. Moreover, the coating station has a device for rotating the coating places on the conveyor device with a substrate or work piece carrier 38, and a device for generating electromagnetic waves 36.

Two sealed coating chambers 40, 41 each having a coating place 91 or 92, respectively, for a substrate that is to be coated and into which electromagnetic energy is introduced to ignite the plasma for the coating, are formed between the sleeve part 34 and the base plate 32 when the latter butt against one another, as illustrated in FIG. 2.

Accordingly, in the embodiment shown in FIG. 2, it is possible for two substrates 11 to be treated simultaneously. Separating the chambers prevents the plasmas from influencing one another during the coating operation.

The coating chambers 40, 41 of the coating station 7 are sealed off from the environment by seals 45 which are arranged between sleeve part 34 and substrate carrier 38.

To coat substrates 11, the latter are arranged on the substrate carrier 38, then the sleeve part 34 is brought together with the substrate carrier 38 by movement of the sleeve part 34, so that in the position in which the two parts butt against one another, sealed coating chambers 40, 41 are defined between sleeve part 34 and substrate carrier 38, and the substrates 11 are located in these coating chambers 40, 41, which are evacuated, then process gas is introduced, and finally a plasma is generated by the introduction of electromagnetic energy, so that a CVD coating is formed on those surfaces of the work pieces which adjoin the plasma.

In this embodiment, the device 36 for generating electromagnetic waves comprises two microwave heads or microwave generators 361 and 362, an adaptor in the form of a rectangular wave guide 363 and two supply conductors or coupling passages 364 and 365, which branch off from this wave guide and in the embodiment illustrated in FIG. 2 are designed as coaxial conductors. The microwave heads preferably generate microwaves at the frequency of 2.45 GHz, which is licensed for use for telecommunications.

In the embodiment illustrated in FIG. 2, to open and close the coating chambers, 40, 41, the sleeve part 34 is moved substantially perpendicular to the base plate 32, in the direction denoted by A. The direction A runs along the supply conductors 364 and 365, so that the sleeve part 34 can be moved along the supply conductors. The conductors simultaneously serve as a guide for the sleeve part 34. Accordingly, to open and close the coating chambers 40, 41, the sleeve part 34 is moved while the substrate carrier 38 is held in place.

Furthermore, the sleeve part 34 has openings 341 and 342, in which the supply conductors 364 and 365 of the device for generating electromagnetic waves engage. Moreover, the supply conductors 364, 365 are provided with dielectric windows 366, 367, such as for example quartz glass windows for introducing the microwaves into the low-pressure or vacuum region of the reactor 18.

The coaxial conductors or supply conductors 364, 365 are also provided with sealing collars, so that when the coating chambers 40, 41 are being closed by movement of the sleeve part, seals 46, 48 between the sealing collars and the sleeve part 34 are compressed, thereby creating a vacuum-tight sealing of the openings 341, 342.

The embodiment of a coating station 7 which is shown in FIG. 2 is specifically designed for the coating of substrates 11 which are in the form of hollow bodies, such as for example the plastic bottles illustrated by way of example in FIG. 2.

For this purpose, the substrate carrier 38 has receptacles for the bottle necks with seals which close off the interior of the substrates 11 in the form of hollow bodies in a vacuum-tight manner with respect to the environment. This allows different pressures to be established inside and outside the substrate, for example in order to be able to produce purely an internal coating or also purely an external coating or to be able to produce different coatings in the interior and on the outer surface of the substrates 11.

Through-passages 50, 51, 52 and 53, which connect that side of the substrate carrier which faces the coating places 91, 92 to the opposite side of the substrate carrier 38, are present in the substrate carrier 38 for evacuation and for supplying process gas. The base plate 32 is brought together with the substrate carrier 38 in order for process gas to be supplied and in order to produce a connection to the evacuation device. Moreover, for this purpose the base plate 32 has supply or coupling passages 54, 55, 56, 57. The through-passages 50 to 54 and the supply passages 54 to 57 are arranged in such a way that the supply passages and through-passages which are in each case assigned to one another are brought into alignment with and connected to one another when the base plate 32 is brought together with the substrate carrier 38. Inter alia, this creates a connection to the evacuation device, so that the coating chambers can be evacuated and process gas can be supplied. In this case, the through-passages 50 to 53 are each assigned to a supply passage 54 to 57. In detail, the supply passages 54 and 56 serve to supply vacuum to the environment surrounding the substrates 11 in the coating chambers 40, 41, and the supply passages 55 and 57 serve to evacuate the interiors of the substrates 11, which have been sealed off with respect to the environment. Moreover, the supply passages 55, 57 and their associated through-passages 51, 53 also serve as through-passages through which gas lances 58, 60 for feeding process gas into the interiors of the substrates 11 can be introduced. The gas lances 58, 60 are secured to a further carrier plate 62 with seals 63, which is brought together with the base plate 32 after the coating chambers have been closed, so that the gas lances project into the interiors of the substrates and the seals 63 seal off the through-passages for the gas lances with respect to the outside.

To allow the pressure required for coating to be reached quickly in the coating chambers 40, 41, a multistage evacuation device having a plurality of pump stages 65, 67, 69 is provided. Furthermore, the evacuation device comprises a device for sequentially connecting the at least one coating station to the plurality of pump stages 65, 67, 69. In this case, valves 80, to which the pump stage provided can be successively connected, serve as the sequential connection device. The valves 82, 83 serve to vent the coating chambers and/or as chamber bleed valves. A bypass line, which connects the supply passages, 54, 56 for evacuating the environment surrounding the substrates to the supply passages 55, 57 for evacuating the interiors of the substrates 11, can be connected or disconnected by means of the valve 81. Accordingly, the valve 81 serves as a chamber vacuum valve. Therefore, the interior of the substrates 11 can be separately connected to the pump stages as a result of the valve 81 being closed, so that the valve 81 serves as a device for separate evacuation of the interior of the substrates 11 in the form of hollow bodies.

FIG. 3 shows a cross-sectional view through an embodiment of a coating station with control of the opening and closing operation by mechanical control cams. The coating station 7 otherwise substantially corresponds to the embodiment illustrated with reference to FIG. 2. Moreover, the coating station 7 is illustrated in the open state, in order to illustrate the loading or removal operation.

The substrate carrier 38 can be rotated about an axis of rotation 39 by means of a device for rotating the coating places 91 to 94, of which coating places 91 and 92 can be seen in FIG. 3. During the loading operation, the substrate carrier 38 with the coating places 91 to 94 is rotated, so that the coating places are accessible from a loading position and the substrates 11 are inserted into the receptacles of the substrate carrier 38. After the insertion of the substrates has ended, the substrate carrier 38 is positioned in such a way that its through-passages are aligned with the supply passages in the base plate, and the sleeve part 34 is brought together with the substrate carrier 38, so as to define sealed coating chambers which can be evacuated via the supply passages in the base plate 32. Then, the gas lances 58, 60 are introduced into the interiors of the substrates 11. In this embodiment of the coating station, both the movement of the sleeve part and the introduction of the gas lances are imparted by mechanical control cams 85 and 86 which are arranged in a fixed position at the apparatus. For this purpose, guide arms 90 and 92 with guide rolls 88, which engage around the control cams 85, 86, are arranged on the sleeve part 34 and on the carrier plate 62. If the coating station 7 is moved on the conveyor device, the guide arms 90, 92 follow the path of the mechanical control cams, the cross-sectional position of which changes in the direction of the arrows A, B illustrated in FIG. 3, so that a movement of the sleeve part 34 in the direction of arrow A and a movement of the carrier plate 62 in the direction of arrow B are imparted.

### List of Reference Symbols

1 Apparatus for the vacuum coating of substrates
3 Conveyor carousel
5 Axis of rotation of 3
7, 71, 72, 73, 74, . . . , 7N Coating stations
91, 92, 93, 94, Coating places
. . . .
11 Substrate
12 Loading sector
14 Evacuation sector
16 Coating sector
18 Venting sector
20 Removal sector
24, 26, 28, 30 Allocation wheels
32 Base plate
34 Moveable sleeve part
341, 342 Openings in 34
36 Device for generating electromagnetic waves
361, 362 Microwave head of 36
363 Rectangular wave guide of 36
364, 365 Supply conductors of 36
366, 367 Dielectric windows
38 Substrate carrier
39 Axis of rotation of 38
40, 41 Coating chambers
45, 46, 48 Seals
50, 51, 52, 53 Through-passages in 38
54, 55, 56, 57 Supply passages in 32
62 Carrier plate
63 Seals of 62
65, 67, 69 Pump stages
80, 81, 83 Valves
85, 86 Mechanical control cam
88 Guide rolls
90, 92 Guide arm

1. An apparatus for the vacuum coating of a plurality of substrates, comprising:
a conveyor device;
at least one coating station having a plurality of coating places, wherein the at least one coating station is conveyed on the conveyor device;
an evacuation device; and
a device for rotating the plurality of coating places on the conveyor device.

2. The apparatus of claim 1, wherein the conveyor device comprises a conveyor carousel or a linear conveyor device.

3. The apparatus of claim 1, wherein the conveyor device is a conveyor carousel having an axis of rotation, wherein the plurality of coating places each have an axis of rotation parallel to the axis of rotation the conveyor carousel.

4. The apparatus claim 1, wherein the at least one coating station comprises a rotatable substrate carrier.

5. The apparatus of claim 4, wherein the rotatable substrate carrier has through-passages that connect a side of the rotatable substrate carrier facing the plurality of coating places to an opposite side of the rotatable substrate carrier.

6. The apparatus as of claim 4, wherein the at least one coating station comprises a base plate with a plurality of supply passages, the plurality of supply passages being connectable with the rotatable substrate carrier to produce a connection to the evacuation device or to supply a process gas.

7. The apparatus claim 1, further comprising a loading device with at least one allocation wheel.

8. The apparatus of claim 1, further comprising a removal device with at least one allocation wheel.

9. The apparatus claim 1, wherein the device for rotating the plurality of coating places on the conveyor device moves the plurality of coating places into a loading position through rotation of the at least one coating station so that the plurality of coating places can be loaded with the plurality of substrates.

10. The apparatus of claim 1, wherein the device for rotating the at least one coating station on the conveyor moves the plurality of coating places into a removal position by rotation of the at least one coating station so that the plurality of substrates can be removed from the plurality of coating places.

11. The apparatus of claim 1, further comprising a plasma coating device for coating the plurality of substrates with plasma.

12. The apparatus of claim 11, wherein the plasma coating device generates electromagnetic waves.

13. The apparatus of claim 11, wherein the plasma coating device introduce a process gas.

14. The apparatus claims 1, wherein the evacuation device comprises a plurality of pump stages.

15. The apparatus claim 1, wherein the evacuation device sequentially connects the at least one coating station to a plurality of pump stages.

16. The apparatus of claim 1, wherein the plurality of coating places have at least one receptacle for the plurality of substrates in the form of a plurality of hollow bodies.

17. The apparatus of claim 16, wherein the evacuation device separately evacuates an interior of each of the plurality of hollow bodies.

18. The apparatus of claim 16, further comprising a device for separately feeding a process gas into an interior of each of the plurality of hollow bodies.

19. The apparatus of claim 1, wherein the at least one coating station comprises a reactor with a moveable sleeve part and a substrate carrier with at least one sealed coating chamber, the at least one sealed coating chamber being defined between the moveable sleeve part and the substrate carrier in a position in which the moveable sleeve part and the substrate carrier butt against one another.

20. The apparatus of claim 1, further comprising at least one lifting device for opening and closing the at least one coating station, the at least one lifting device being selected from the group consisting of a pneumatic lifting device, a hydraulic lifting device, and an electrical lifting device.

21. The apparatus of claim 1, further comprising at least one mechanical control cam for opening and closing the at least one coating station.

22. The apparatus of claim 1, further comprising a PVD coating device for the PVD coating of the plurality of substrates.

23. A process for the vacuum coating of a plurality substrates, comprising the steps of:
loading a coating station having a number of coating places with a number of the plurality of substrates that are to be coated;
evacuating the coating station;
conveying the coating station on a conveyor device;
vacuum coating the plurality of substrates;
venting the coating station; and
removing the number of coated substrates, wherein the plurality of coating places are rotated on the conveyor device.

24. The process of claim 23, wherein the coating station is conveyed on a conveyor carousel or a linear conveyor device.

25. The process of claim 23, wherein the coating station is conveyed on a conveyor carousel having an axis of rotation, and wherein the plurality of coating places each have an axis of rotation that is parallel to the axis of rotation of the conveyor carousel.

26. The process of claim 23, wherein the loading of the coating station with the number of substrates that are to be coated is effected by an allocation of a plurality of wheels of a loading device.

27. The process of claim 23, wherein the plurality of coating places are successively moved into a plurality of loading positions.

28. The process of claim 23, wherein the plurality of coating places are successively moved into a plurality of removal positions.

29. The process of claim 27, wherein the rotation of the plurality of coating places comprises the rotation of a substrate carrier.

30. The process of claim 29, further comprising bringing together a base plate having a plurality of supply passages with the substrate carrier so that a connection to the evacuation device or to a supply of process gas is produced.

31. The process of claim 30, wherein the substrate carrier has a plurality of through-passages connecting a side of the substrate carrier facing the plurality of coating places to an opposite side of the substrate carrier, and wherein the plurality of through-passages connected to the plurality of supply passages positioned in the base plate when the base plate is brought together with the substrate carrier.

32. The process of claim 23, wherein the step of vacuum coating of the plurality of substrates comprises plasma coating.

33. The process of claim 32, further comprising generating a plurality of plasma electromagnetic waves, and feeding the plurality of plasma electromagnetic waves to the plurality of coating places.

34. The process of claim 33, wherein the plurality of plasma electromagnetic waves are pulsed.

35. The process of claims 23, wherein the step of evacuating the coating station is carried out in a plurality of stages.

36. The process of claim 23, wherein the plurality of substrates are in the form of a plurality of hollow bodies, and wherein the process further comprises separately evacuating an interior of each of the plurality of hollow bodies.

37. The process of claims 36, further comprising feeding process gas separately into the interior of each of the plurality of hollow bodies.

38. The process of claim 37, further comprising introducing a plurality of electromagnetic waves into the coating station to ignite a plasma in the interior of each of the plurality of hollow bodies to internally coat the plurality of substrates.

39. The process of claim 23, wherein the step of vacuum coating the plurality of substrates comprises PVD coating of the plurality of substrates.

40. The process of claim 23, wherein the step of removing the number of coated substrates is effected by an allocation of a plurality of wheels of a unloading device.
